(19) United States
(12) Patent Application Publication
(10) Pub. No.: US 2015/0333745 A1
(43) Pub. Date: Nov. 19, 2015

(54) VOLTAGE COMPARATOR

(71) Applicant: LSI Corporation, Milpitas, CA (US)

(72) Inventor: Naveen Kumar Cannankurichi Vijaya Mohan, Hyderabad (IN)

(73) Assignee: LSI Corporation, Milpitas, CA (US)

(21) Appl. No.: 14/279,677

(22) Filed: May 16, 2014

(51) Int. Cl. H03K 5/125; H03K 17/56

(52) U.S. Cl. CPC H03K 5/125; H03K 17/56

(57) ABSTRACT

A voltage comparator for comparing reference voltage applied to a first input node to an input voltage applied to a second input node. A first pair of transistors have output terminals coupled in series between the first input node and common node, and gate terminals connected together. A second pair of transistors, having both gate terminals of the pair connected to the gate terminals of the first pair of transistors, have output terminals coupled in series between a second input terminal, an intermediate node, and the common node. An inverter has an input coupled to the intermediate node and an output coupled to an output of the comparator. An optional feedback transistor might be used to latch the output of the comparator. Optional transistors might also be added to the first and second transistor pairs to selectively enable as the comparator and reset the latched output of the comparator.

### BACKGROUND

1. Field of the Invention

The present invention relates to voltage comparators generally and, more specifically, to voltage comparators for power supply voltage monitoring such as switching voltage regulators or the like.

2. Description of the Related Art

Power supply monitoring circuits are widely used to protect processors and other circuitry from operating with power supply voltages outside of a desired voltage range. For example, because one or more voltages of a system power supply ramps up and down as the system is powered on and off, it is desirable that a processor in the system is not enabled until all of the power supply voltages reaches minimum operating voltages and that the processor is disabled if any of the power supply voltages subsequently drop below the corresponding minimum operating voltages or if any of the power supply voltages exceed a corresponding maximum operating voltage. Alarm flags might also be generated indicating that an out-of-range power supply voltage condition exists.

There is a trend to reduce the operating voltage of the processor to reduce power consumption as switching speeds increase. Concomitantly, the range of the operating voltage (i.e., the difference between the maximum and minimum operating voltage) is narrowed. For example, a typical operating voltage is 4.75 volts minimum to 5.25 volts maximum for a nominal 5 volt operating, voltage processor results in an operating range of 500 mV. But for a processor configured to operate with a nominal 1.8 volt supply voltage, the specified operating voltage is from 1.65 to 1.95 volts which results in an operating range of 300 mV. Thus, the accuracy of measuring the supply voltage becomes more acute as the operating voltage decreases.

To determine if the power supply voltages meet the minimum and maximum operating voltages, a plurality of comparators are typically provided that compare the power supply voltages to corresponding reference voltages. However, the accuracy of each of the comparators, i.e., the difference in voltage between what is being measured and a reference voltage that causes the output of a comparator to change state, is substantially determined by offsets in the transistors used to sense the difference in voltage. These offsets might arise from slight differences is sizes of the transistors or variations in bias currents within a comparator. While the size differences are generally set by the processing technology used to make the comparator, bias current variations can be controlled only to a limited extent where multiple bias currents are used. Thus, it is desirable to have a comparator that reuses bias currents in such a way that no substantial difference in bias currents exists in the comparator.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In one embodiment of the invention, a voltage comparator providing an output signal is disclosed. The comparator has a first input node and a second input node, a first transistor, a second transistor, a third transistor, a fourth transistor, and an inverter. The first transistor is of a first polarity has a first output terminal connected to the first input node, a second output terminal coupled to a first intermediate node, and an input terminal connected to the first intermediate node. The second transistor is of the first polarity and has a first output terminal connected to the second input node, a second output terminal coupled to a second intermediate node, and an input terminal connected to the input terminal of the first transistor. The third transistor is of a second polarity and has a first output terminal coupled to the first intermediate node, a second output terminal connected to a common node, and an input terminal connected to the first intermediate node. The fourth transistor is of the second polarity and has a first output terminal coupled to the second intermediate node, a second output terminal connected to a common node, and an input terminal connected to the input terminal of the third transistor. The inverter has an input coupled to the second intermediate node and an output coupled to the output of the comparator.

### BRIEF DESCRIPTION OF THE DRAWINGS

Other embodiments of the present invention will become more fully apparent from the following detailed description, the appended claims, and the accompanying drawings in which like reference numerals identify similar or identical elements.

FIG. 1 is a simplified schematic diagram of a voltage comparator according to one or more embodiments of the invention; and

FIG. 2 is an exemplary embodiment of a system haying a power supply voltage monitor utilizing the voltage comparator of FIG. 1.

### DETAILED DESCRIPTION

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation”.

It should be understood that the steps of the exemplary methods set forth herein are not necessarily required to be performed in the order described, and the order of the steps of such methods should be understood to be merely exemplary, Likewise, additional steps might be included in such methods, and certain steps might be omitted or combined, in methods consistent with various embodiments of the present invention.

Also for purposes of this description, the terms “couple”, “coupling”, “coupled”, “connect”, “connecting”, or “connected” refer to any manner known in the art or later developed in which energy is allowed to transfer between two or more elements, and the interposition of one or more additional elements is contemplated, although not required. Conversely, the terms “directly coupled”, “directly connected”, etc., imply the absence of such additional elements. Signals and corresponding nodes or ports might be referred to by the same name and are interchangeable for purposes here. The term “or” should be interpreted as inclusive unless stated otherwise. Further, source and drain terminals of transistors might also referred to as output terminals and gate terminals might also be referred to as input terminals.

The present invention will be described herein in the context of illustrative embodiments of a voltage comparator for use in a power supply monitor or the like. It is to be appreciated, however, that the invention is not limited to the specific apparatus and methods illustratively shown and described herein,

In one embodiment, the voltage comparator is used to monitor a system supply voltage to detect a collapse in the supply voltage during power failure or for determining if the supply voltage has reached a voltage sufficient for normal system operation or has exceeded an upper voltage limit. In another embodiment, the comparator is used to continuously monitor a supply voltage during normal operation.

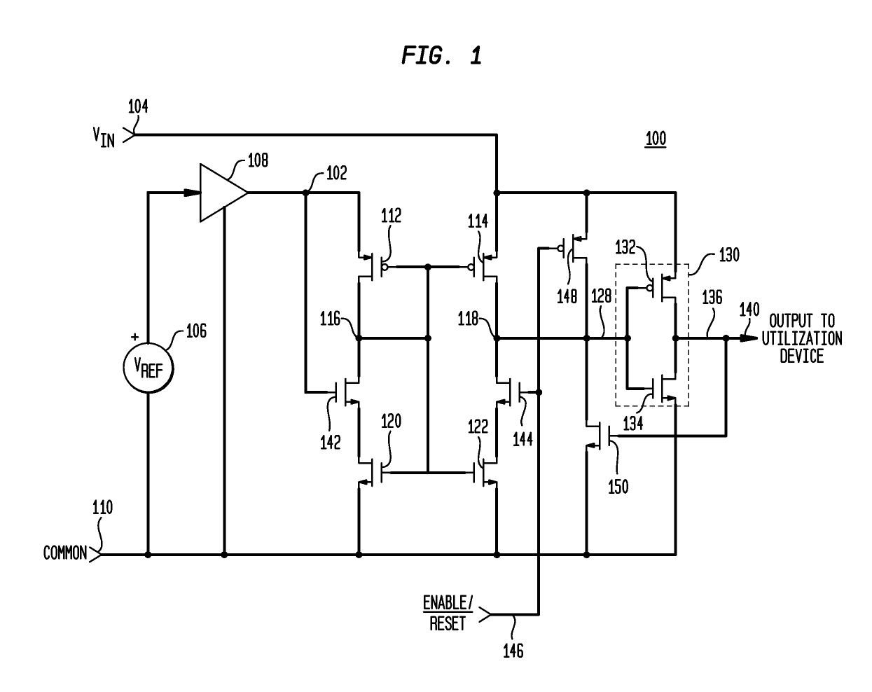

FIG. 1 is a simplified schematic diagram of a comparator 100 according to an embodiment of the invention. The comparator 100 has a first input node 102 and a second input node 104 receiving voltages for comparison to each other. In one embodiment, the first input node 102 receives a buffered reference voltage V_{REF} from a voltage source 106. Buffer 108 might be an operational amplifier configured as a unity-vain buffer. The voltage source 106 and buffer 108 are connected to a common node 110 that is used as a reference point for all applied voltages and might be ground (zero volts).

The reference voltage source 106 is preferably substantially temperature invariant (e.g., by using, a conventional bandgap-referenced voltage source) although in certain embodiments having a reference voltage that varies with temperature might be desirable.

Node 102 is coupled to a source terminal (an output terminal) of a first transistor 112 (here a P-channel metal-oxide-semiconductor transistor or PMOS transistor) connected in a diode configuration with the drain terminal thereof (an output terminal of the PMOS transistor 112) connected to the gate terminal thereof and to a first intermediate node 116. Node 104 is coupled to a source terminal of a second transistor 114 (here also a PMOS transistor) and the drain terminal connected to a second intermediate node 118. A gate terminal of the PMOS transistor 114 is connected to the gate terminal of MOS transistor 112. A third transistor 120 (here an N-channel metal-oxide-semiconductor transistor or NMOS transistor) has a drain terminal coupled to the first intermediate node 116 and a source terminal connected to the common node 110. A gate terminal of the NMOS transistor 120 connects to the first intermediate node 116. A fourth transistor 122 (here also an MOOS transistor) has a source terminal connected to the common node 110, a drain terminal coupled to the second intermediate node 118, and a gate terminal connected to the gate terminal of the NMOS transistor 120. Connected to the second intermediate node 118 is an input 128 of a conventional inverter 130 composed of a PMOS transistor 132 and a NMOS transistor 134. The inverter 130 has an output 136 which connects to the output 140 of the comparator 100. The inverter 130 is powered from the first input node 104 and the common node 110.

Optional NMOS transistors 142 and 144 are disposed between the drains of N MOS transistors 120, 122 and intermediate nodes 116, 118, respectively. The gate terminal of NFET 142 is connected to the first intermediate node 102 and the gate terminal of NMOS transistor 144 is connected to a control node 146. NMOS transistor 144, in response to the signal on control node 146, is used to enable or disable the comparator 100. Transistor 142, having a gate terminal connected to input node 102, compensates for the presence of NMOS transistor 144 between the intermediate node 118 and the drain terminal of NMOS transistor 122. In one embodiment, when the control signal on node 146 is “high”, the voltage on the gate terminal of NMOS transistor 144 is approximately that of the voltage on input node 104. Thus, when the voltages on nodes 102 and 104 are approximately the same and the output of the comparator 100 might change state, the accuracy of the comparator 100 is not significantly compromised by the presence of the transistors 142, 144 since both transistors are subject to substantially the same voltages and currents, assuming that transistors 142, 144 are substantially the same size. In another embodiment, the transistors 42, 144 are not present and the drain terminal of NMOS transistor 120 is connected to the first intermediate node 116 and the drain terminal of NMOS transistor 122 is connected to the second intermediate node 118.

Optional PMOS transistor 148 couples the second intermediate node 118 to the first input node 104 when the control signal is “low” such that the transistor 144 is disabled. This assures a stable, known voltage on node 118 and on input 128 of inverter 130. If transistors 142 and 144 are not present, there might not be a need for transistor 148.

Optional feedback NMOS transistor 150 has a drain terminal connected to the second intermediate node and a source terminal connected to the common node 110. The gate terminal of transistor 150 in connected to the output 136 of the inverter 130. The transistor 150 serves to latch the output of the inverter in a high state (e.g., when the voltage on node 102 is greater than the voltage on node 104 and the enable signal on control node 146 is “high”). When transistor 150 is present, then to clear or unlatch the inverter 130, the control signal on control node 146 is brought “low” to pull the node 118 high and driving the output of the inverter 130 low and disabling the transistor 150. In this instance, transistor 150 is much smaller than transistor 148 so that transistor 148 might “dominate” transistor 150 when both are on.

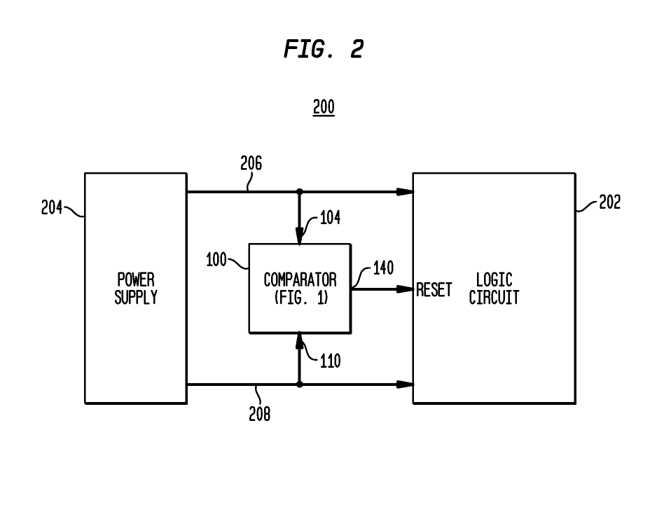

FIG. 2 illustrates an embodiment where the voltage comparator 100 of FIG. 1 is used to monitor a power supply voltage for a logic circuit 202, such as a processor. The system 200 consists of a power source 204 that provides a regulated voltage on lines 206, 208 with sufficient current to power the logic circuit 202 and any other circuitry connected thereto. In this embodiment, the above-described comparator 100, having the second input node 104 connected to line 206 and the common node 110 connected to line 208, shuts down the logic circuit by asserting a reset signal to logic circuit 202 while a voltage difference between lines 206 and 208 is less than a minimum voltage. In an alternative embodiment, the comparator 100 shuts down the logic circuit while the voltage difference between lines 206 and 208 exceeds a maximum voltage.

In another embodiment of the invention, the NMOS transistors 120, 122, 134, 142, 144, and 150 are replaced with PMOS transistors and PMOS transistors 112, 114, 132, and 148 are replaced with NMOS transistors and the reference voltage changed with suitable change in bias and supply voltage polarities as is well known in the art.

Generally, the sizes of the transistors 112, 114 are substantially the same, the sizes of transistors 120, 122 are substantially the same, and the sizes of transistors 142, 144 are substantially the same. Further, the size of transistors 112, 114 might be three times the size of transistors 120, 122. Similarly, the size of transistor 132 might be substantially the same as the size of transistors 112, 114 and the size of transistor 134 might be substantially the same as the size of transistors 120, 122.

It will be further understood that various changes in the details, materials, and arrangements of the parts that have been described and illustrated in order to explain the nature of this invention may be made by those skilled in the art without departing from the scope of the invention as expressed in the following claims.

1. A comparator having an output, comprising:
a first input node;
a second input node;
a first transistor of a first polarity having a first output terminal connected to the first input node, a second output terminal coupled to a first intermediate node, and an input terminal connected to the first intermediate node;
a second transistor of the first polarity ha mg a first output terminal connected to the second input node, a second output terminal coupled to a second intermediate node, and an input terminal connected to the input terminal of the first transistor;
a third transistor of a second polarity having a first output terminal coupled to the first intermediate node, a second output terminal connected to a common node, and an input terminal connected to the first intermediate node;
a fourth transistor of the second polarity having a first output terminal coupled to the second intermediate node, a second output terminal connected to a common node, and an input terminal connected to the input, terminal of the third transistor; and
an inverter, having an input coupled to the second intermediate node, and an output coupled to the output of the comparator.

2. The comparator of claim 1 further comprising:
a fifth transistor of the second conductivity type having output terminals connected between the first output terminal of the third transistor and the first intermediate terminal, and an input terminal connected to the first input node; and
a sixth transistor of the second conductivity type having output terminals connected between the first output terminal of the fourth transistor and the second intermediate terminal, and an input terminal connected to a control input.

3. The comparator of claim 2, further comprising:
a seventh transistor of the first conductivity type having one output terminal connected to the second input node, a second output terminal coupled to the second intermediate node, and an input terminal connected to the control input; and
a feedback transistor having an output terminals connected between the input of the inverter and the common node, and an input terminal connected to the output of the inverter.

4. The comparator of claim 1 wherein the inverter comprises:
a pull-up transistor of the first conductivity type, having output terminals connected between the second input node and the output of the inverter, and an input terminal connected to the input of the inverter; and
a pull-down transistor of the second conductivity type, haying output terminals connected between the common node and the output of the inverter, and an input terminal connected to the input of the inverter.

5. The comparator of claim 4 wherein the transistors of the first conductivity type are substantially the same size and the transistors of the second conductivity are substantially the same size.

6. The comparator of claim 5 wherein the transistors of the first conductivity type are substantially three times the size of the transistors of the second conductivity type.

7. The comparator of claim 6 wherein the transistors of the first conductivity type are P-type metal-oxide-semiconductor transistors, and transistors of the second conductivity type are N-type metal-oxide-semiconductor transistors.

8. The comparator of claim 1 further comprising:
a voltage buffer having an output connected to the first input node; and
a reference voltage source coupled to an input of the voltage buffer.

9. A system comprising:
a power supply;
a logic circuit having a reset input and power input nodes coupled to the power supply;
the comparator of claim 8 having the second input node and the common node connected to the power supply, and the output of the comparator connected to the reset input of the logic circuit.

10. A comparator having an output, comprising:
a first input node;
a second input node;
a first transistor of a first polarity having a first output terminal connected to the first input node, a second output terminal, and an input terminal connected to the second output terminal;
a second transistor of the first polarity haying a first output terminal connected to the second input node, a second output terminal, and an input terminal connected to the input terminal of the first transistor;
a third transistor of a second polarity having a first output terminal, a second output terminal connected to a common node, and an input terminal connected to the input terminal of the first transistor;
a fourth transistor of the second polarity having a first output terminal, a second output terminal connected to a common node, and an input terminal connected to the input terminal of the third transistor;
a fifth transistor of the second conductivity type having output terminals connected between the first output terminal of the third transistor and the second output terminal of the first transistor, and an input terminal connected to the first input node; and
a sixth transistor of the second conductivity type having output terminals connected between the first output terminal of the fourth transistor and the second output terminal of the second transistor, and an input terminal connected to a control input;
a pull-up transistor of the first conductivity type, having output terminals connected between the second input node and the output of the comparator, and an input terminal coupled to the second output terminal of the second transistor; and
a pull-down transistor of the second conductivity type, having output terminals connected between the common node and the output of the comparator, and an input terminal coupled to the second output terminal of the second transistor.

11. The comparator of claim 10, further comprising:
a seventh transistor of the first conductivity type having one output terminal connected to the second input node, a second output terminal coupled to the first output terminal of the first transistor, and an input terminal connected to the control input.

12. The comparator of claim 10 further comprising:
a voltage buffer having an output connected to the first input node; and
a reference voltage source coupled to an input of the voltage buffer.

13. The comparator of claim 10 wherein the transistors of the first conductivity type are substantially the same size and the transistors of the second conductivity are substantially the same size.

14. The comparator of claim 13 wherein the transistors of the first conductivity type are substantially three times the size of the transistors of the second conductivity type.

15. The comparator of claim 14 wherein the transistors of the first conductivity type are P-type metal-oxide-semiconductor transistors, and transistors of the second conductivity type are N-type metal-oxide-semiconductor transistors.

16. A comparator haying an output, comprising:
a first input node;
a second input node;
a first transistor of a first polarity having a first output terminal connected to the first input node, a second output terminal, and an input terminal connected to the second output terminal;
a second transistor of the first polarity haying a first output terminal connected to the second input node, a second output terminal, and an input terminal connected to the input terminal of the first transistor;
a third transistor of a second polarity haying a first output terminal, a second output terminal connected to a common node, and an input terminal connected to the input terminal of the first transistor;
a fourth transistor of the second polarity having a first output terminal, as second output terminal connected to a common node, and an input terminal connected to the input terminal of the third transistor;
a fifth transistor of the second conductivity type having output terminals connected between the first output terminal of the third transistor and the second output terminal of the first transistor, and an input terminal connected to the first input node; and
a sixth transistor of the second conductivity type having output terminals connected between the first output terminal of the fourth transistor and the second output terminal of the second transistor, and an input terminal connected to a control input;
a seventh transistor of the first conductivity type having a first output terminal connected to the second input node, a second output terminal connected to the second output terminal of the second transistor, and an input terminal connected to the control input;
a pull-up transistor of the first conductivity type, having output terminals connected between the second input node and the output of the comparator, and an input terminal connected to the second output terminal of the second transistor; and
a pull-down transistor of the second conductivity type, having output terminals connected between the common node and the output of the comparator, and an input terminal connected to the second output terminal of the second transistor.

17. The comparator of claim 16 further comprising:
a voltage buffer having an output connected to the first input node; and
a reference voltage source coupled to an input of the voltage buffer.

18. The comparator of claim 16 wherein the transistors of the first conductivity type are substantially the same size and the transistors of the second conductivity are substantially the same size.

19. The comparator of claim 18 wherein the transistors of the first conductivity type are substantially three times the size of the transistors of the second conductivity type.

20. The comparator of claim 19 wherein the transistors of the first conductivity type are P-type metal-oxide-semiconductor transistors, and transistors of the second conductivity type are N-type metal-oxide-semiconductor transistors.
